(19) United States
(12) Patent Application Publication
(10) Pub. No.: US 2007/0242498 A1
(43) Pub. Date: Oct. 18, 2007

(54) Sub-threshold static random access memory

(76) Inventors: Anantha Chandrakasan, Belmont, MA (US); Benton H. Calhoun, Charlottesville, VA (US)

Correspondence Address: James W. Wiegand, Suite 700, 60 State Street, Boston, MA, 02109, US

(21) Appl. No.: 11/403,690

(22) Filed: Apr. 13, 2006

(51) Int. Cl. G11C 11/00; G11C 8/00

(52) U.S. Cl. 365/154; 365/230.06

(57) ABSTRACT

A static random access memory is configured for operation at sub-threshold voltage levels. A bistable circuit is supplemented by buffer circuitry configured to improve read performance and float circuitry to improve write performance.

### FIELD OF THE INVENTION

The invention relates to integrated circuits and, more particularly, to static random access memories.

### BACKGROUND OF THE INVENTION

Although many applications that require the use of static electronic memory (referred to herein as static random access memory or SRAM) are well-served by conventional SRAM devices, a great number of applications would benefit from or are only feasible with extremely low power operation.

The 6T cell of FIG. 1 has remained the bitcell of choice for static random access memory (SRAM) designs because of its relatively wide noise margins. The bitcell 100 comprises a bi-stable flip-flop cell having a data storage node ST and a data bar storage node QB. The bi-stable flip-flop cell preferably consists of a two inverter arrangement where the output of each inverter is coupled to the input of the other inverter. More specifically, the first inverter INV1 includes a pull-up transistor M3 and a pull-down transistor M1. The second inverter INV2 includes a pull-up transistor M6 and a pull-down transistor M4. The pull-up transistors are typically p-channel, or PMOS, transistors, and the pull-down transistors are typically n-channel, or NMOS, transistors.

The bi-stable inverter pair (INV1, INV2) can maintain either of two states: ST at a low voltage (VSS), and QB at a high voltage (VCC), or ST at a high voltage (VSS), and QB at a low voltage (VCC). The inverters will maintain either state indefinitely in the absence of an, external disruption. Access transistors M2 and M5 gate external access to the bi-stable pair.

Both M2 and M5 are controlled by the word line WL signal. If WL is low, then both M2 and M5 are OFF. The bi-stable inverter storage nodes are then isolated from the bit line BL and BLB signals and will simply maintain the current state. If WL is high, then both M2 and M5 are ON causing BL to be coupled to ST and BLB to be coupled to STBAR. If the WL assertion is due to a READ operation, then the BL and BLB signals are high impedance and the charge on ST and on STBAR are coupled onto the BLB and BL buses, respectively, for sensing. If the WL assertion is due to a WRITE operation, then the BL and BLB signals are low impedance and are driven to opposite states. These states are driven into the bi-stable pair to update the states of ST and STBAR.

Typically, an array of bitcells is arranged into rows and columns. Each row lies along a word line WL and each column is associated with a bitline BL pair. The memory address is divided into a row address and a column address. Decoder circuits use the applied address to select the correct wordline and bitline pair for a memory access. For a write access, the wordline is asserted (set “HIGH”) to turn on a row of access transistors, including, in this example, the access transistors M2 and M5. The bitlines (BL and BLB) are driven to the correct differential value to write into the cell. The bitline driving a “0” will overwrite the data held by the cross-coupled inverters. For a read access, the bylines are precharged to “1”, then the wordline is asserted at the same time as the bylines are allowed to float. The internal node of the bitcell that holds a “0” will pull its bitline low through the access transistor. Typically, a sense amplifier detects this differential voltage on the bitlines while it is still relatively low-level and amplify it to full voltage. When a bitcell is holding data, its wordline is low, so M2 and M5 are off. In order to hold its data properly, the back-to-back inverters (INV1, INV2) must maintain bistable operating points.

The standard cross-coupled inverter SRAM cell of FIG. 1 is not particularly suitable for low-power applications. In the sub-threshold region a mismatch of currents prevent the standard write operation from overpowering the 6T cell's feedback. As the SRAM supply voltage is decreased, local variations in the 6T cells' threshold voltages diminish the 6T cell's static noise margin (SNM) during read operations to the point that such a circuit becomes completely impractical. Additionally, bitline leakage severely hampers the read operation and severely limits the number of cells that may share a bitline. That is, although major efforts have been mounted to operate digital logic circuits in the sub-threshold region and to thereby capture significant power savings, no RAM circuits have been developed to operate in the sub-threshold region. Efforts at developing sub-threshold SRAM are chronicled in, “Low Energy Digital Circuit Design Using Sub-Threshold Operation,” by Benton Highsmith Calhoun, one of inventors of the subject matter of the current application. This thesis is hereby incorporated by reference in its entirety. A memory that operates in sub-threshold, is disclosed in, “A180 mV FFT Processor Using Sub-threshold Circuit Techniques,” in IEEE International Solid-State Circuits Conference (ISSCC) Digest of Technical Papers, 2004, pp. 292-293, Alice Wang and Anantha Chandrakasan, which is also hereby incorporated by reference. That bitcell design employs tristate transistors and, with an eighteen-transistor bitcell, may consume more resources than is desirable. Furthermore, the tristate devices in the bitcell cutoff the bitcell feedback during write operations, and the output is read through multiplexors. These characteristics make the 180 mV memory very similar to a register file, more so than an SRAM.

In order to provide compatibility with sub-threshold logic and to thereby significantly reduce the power requirements of SRAM circuitry and, because SRAM circuitry accounts for a significant portion of power consumed by mixed-use circuits, by extension to significantly reduce the power consumption of mixed-use circuits, an SRAM that is fully operational in sub-threshold would be highly desirable.

### SUMMARY

An apparatus in accordance with the principles of the present invention comprises at least one memory cell composed of a plurality of transistors, none of which are configured as tristate transistors, the cell configured to operate in the sub-threshold region of the cells' constituent transistors.

An SRAM cell in accordance with the principles of the present invention includes a bistable block, a buffer block connected between the bistable block and the cell read bitline(s), and a float block configured to float the supply voltage to the bistable block. In an illustrative embodiment, the buffer block buffers stored data during a read access and the float block floats the supply voltage to cells that are selected for a write operation. Read and write bitlines may be separate, as in this illustrative example, or shared.

In an illustrative embodiment, six transistors are configured to form a bistable circuit of cross-coupled inverters, with access transistors. Three transistors are configured to buffer the connection between the access transistors and the cell's associated bitlines. In a ten-transistor variation, four transistors are configured to buffer the connection between the access transistors and the cell's associated bitlines. In an illustrative embodiment, an additional transistor for each row of 128 bitcells is configured to float the supply voltage to the bistable circuit. In another aspect of an SRAM bitcell in accordance with the principles of the present invention, the SRAM provides read access through a shared bitline and write access without extra transistors in the bitcell dedicated to eliminating feedback.

A sub-threshold SRAM array in accordance with the principles of the present invention is particularly well-suited for operation in mixed use circuits that, for example, include digital logic circuitry. The digital logic circuitry may include, for example, a microprocessor core so that, in an illustrative embodiment, an integrated circuit in accordance with the principles of the present invention incorporates a microprocessor and sub-threshold SRAM on a single chip.

Additionally, a sub-threshold SRAM in accordance with the principles of the present invention may be combined with components to create a wide variety of low-power devices, including, but not limited to, cellular telephones, media playback devices, radio frequency identification tags, microsensor nodes, cameras, and personal digital assistants (PDAs), for example.

### BRIEF DESCRIPTION OF THE DRAWINGS

The above and further features, aspects, and advantages of the invention will be apparent to those skilled in the art from the following detailed description, taken together with the accompanying drawings in which:

FIG. 1 is a schematic diagram of a conventional 6T SRAM cell;

FIG. 2 is a block diagram of a sub-threshold SRAM cell in accordance with the principles of the present invention;

FIG. 3 is a schematic diagram of an illustrative embodiment of an SRAM circuit in accordance with the principles of the present invention;

FIG. 4 is a schematic diagram that illustrates the leakage characteristics of a buffer in accordance with the principles of the present invention in greater detail;

FIG. 5 is a schematic diagram that illustrates the circuitry associated with floating the power supply to a single row during a write operation in accordance with the principles of the present invention in greater detail;

FIG. 6 is a timing diagram that details the timing related to a write operation in accordance with the principles of the present invention, in particular, point (a) shows that the floating power supply is tied back to the full supply voltage while WL=1 such that the internal data values return to the correct digital voltages;

FIG. 7 is block diagram of an illustrative SRAM architecture in accordance with the principles of the present invention;

FIG. 8 is a block diagram of a mixed-use circuit in accordance with the principles of the present invention;

FIG. 9 is a block diagram of a mixed-use circuit in accordance with the principles of the present invention in which digital logic includes a core microprocessor;

FIG. 10 is a block diagram of a portable electronic device that includes a SRAM in accordance with the principles of the present invention; and

FIG. 11 is a block diagram of a network of portable electronic devices that include an SRAM in accordance with the principles of the present invention.

### DETAILED DESCRIPTION

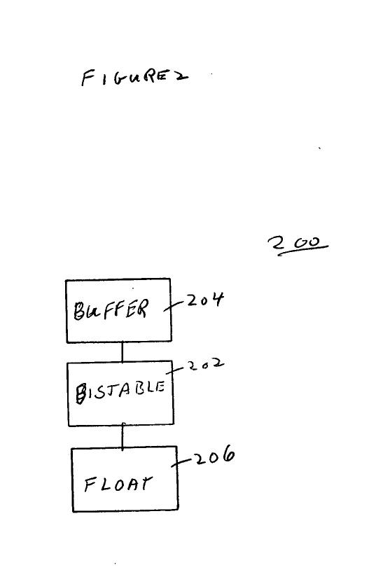

The schematic diagram of FIG. 2 is of an illustrative embodiment of an SRAM bitcell 200 in accordance with the principles of the present invention. In this illustrative embodiment a bistable circuit 202 performs the storage function associated with a conventional SRAM bitcell. A buffer circuit 204 is configured to buffer stored data during a read access. A float circuit 206 is configured to float the supply voltage to the bistable circuit 202.

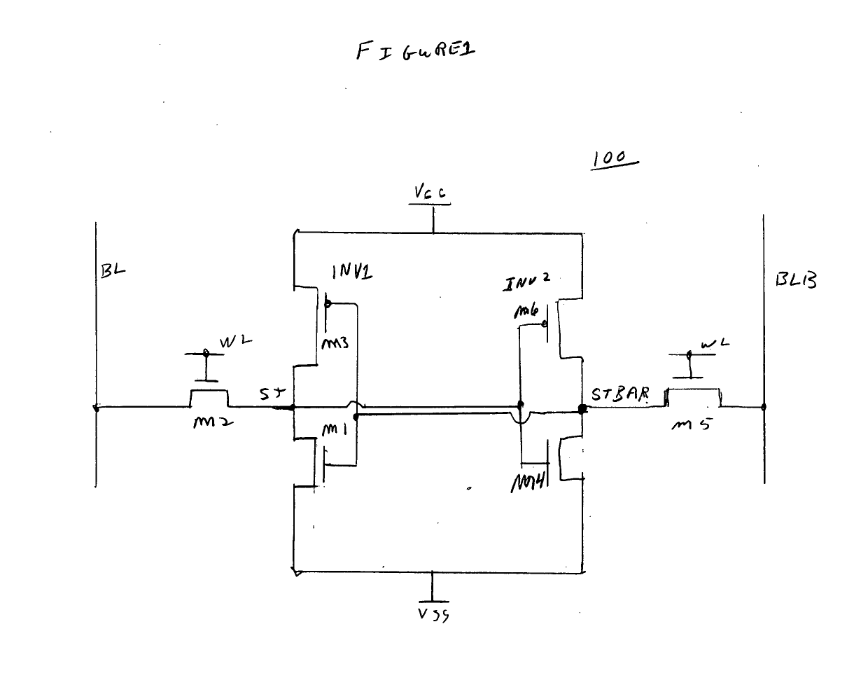

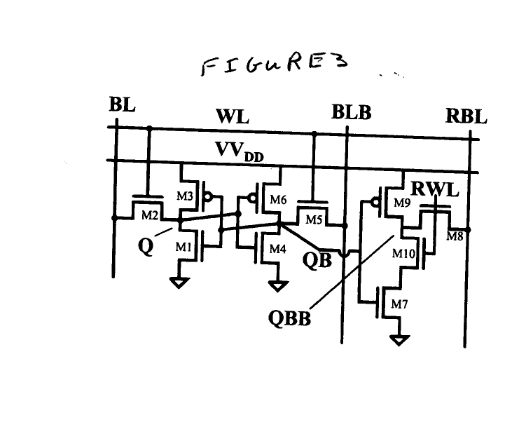

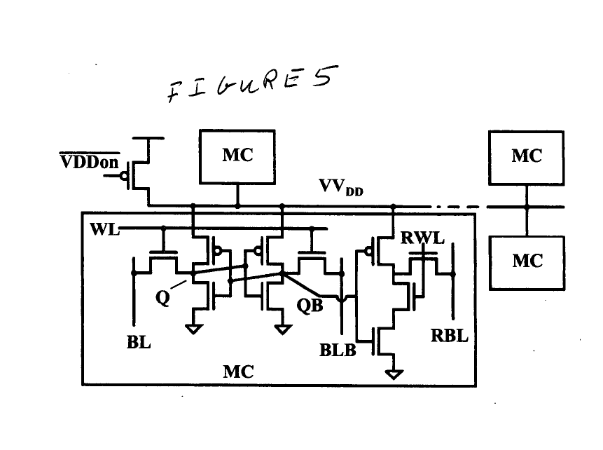

The schematic diagram of FIG. 3 illustrates an embodiment of a subthreshold SRAM bitcell in accordance with the principles of the present invention. The operation of transistors M1 through M6 are as described in relation to the discussion of FIG. 1. The bitcell 300 comprises a bi-stable flip-flop cell having a data storage node Q and a data bar storage node QB. The bi-stable flip-flop-cell preferably comprises a two inverter arrangement where the output of each inverter is coupled to the input of the other inverter. More specifically, the first inverter INV1 includes a pull-up transistor M3 and a pull-down transistor M1. The second inverter INV2 includes a pull-up transistor M6 and a pull-down transistor M4. The pull-up transistors are typically p-channel, or PMOS, transistors, and the pull-down transistors are typically n-channel, or NMOS, transistors. In this illustrative embodiment the pull-up transistors M3, M9 and M6 are connected through their sources to a virtual supply voltage rail VVDD. As described in greater detail in the discussion related to FIG. 5, in this illustrative embodiment the virtual supply voltage rail is connected through float circuitry to a supply voltage rail Vdd. Other supply-floating connections, such as floating the connection between the pulldown transistors' drains and a reference or “ground” rail are contemplated within the scope of this invention.

The bi-stable inverter pair (INV1, INV2) can maintain either of two states: Q at a low voltage (VSS), and QB at a high voltage (VCC), or Q at a high voltage (VSS), and QB at a low voltage (VCC). The inverters will maintain either state indefinitely in the absence of an external disruption. Access transistors M2 and M5 gate external access to the bi-stable pair. Write access to the cell 300 occurs through the access transistors, M2 and M5, from the write bitlines, BL and BLB. In accordance with the principles of the present invention, a buffer is included for use during read operations. In this illustrative embodiment, the buffer includes transistors M7, M8, M9, and M10 configured for operation as follows. Read access is single-ended and occurs on a separate bitline, RBL, which is precharged prior to read access. The wordline for read is distinct from the write wordline. By separating the read and write wordlines and bitlines, a memory using this bitcell can have distinct read and write ports. Since a 6T bitcell does not have this feature, the 10T bitcell is in some ways more accurately compared to an 6T dual-port bitcell (6T bitcell with two pairs of access transistors and bitlines).

Both M2 and M5 are controlled by the word line WL signal. If WL is low, then both M2 and M5 are OFF. The bi-stable inverter storage nodes are then isolated from the bit line BL and BLB signals and will simply maintain the current state. If WL is high, then both M2 and M5 are ON causing BL to be coupled to QB and BLB to be coupled to Q. If the WL assertion is due to a READ operation, then the BL and BLB signals are high impedance and the charge on Q and on QB are coupled onto the BLB and BL buses, respectively, for sensing. If the WL assertion is due to a WRITE operation, then the BL and BLB signals are low impedance and are driven to opposite states. These states are driven into the bi-stable pair to update the states of Q and QB.

Transistors M7, M8, M9 and M10 are configured to buffer stored data during a read access. In operation, when the read wordline (RWL) goes high, the pre-charged read bitline (RBL) creates a voltage divider across M7, M8, and M10, but the increased voltage at QBB does not impact the stored data at Q and QB. Consequently, the worst-case SNM for this bitcell is the Hold SNM related to M1-M6. This is a significant improvement over the Read SNM of a M1-M6 cell. Eliminating the Read SNM problem allows the bitcell of FIG. 3 to provide the same 6 sigma stability as a 6T cell while operating at half the supply voltage. Eliminating the M10 transistor would provide the same Read SNM performance, but M10 reduces leakage current and thereby allows more bitcells to share a bitline. Additionally, in accordance with the principles of the present invention, a single wordline, rather than separate read and write wordlines, may be employed. In such a configuration, the gates of M10 and M8 (or, in a 9T configuration, the gate of M8) would be connected to the wordline WL, rather than to a separate read wordline RWL.

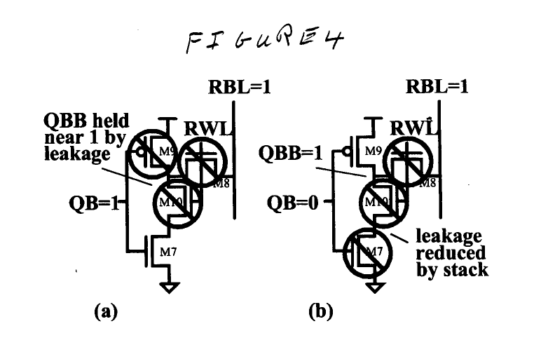

The schematic diagrams of FIGS. 4A and 4B illustrate the operation of the M7-M10 buffer in greater detail. In FIG. 4A, Q=0 and in FIG. 4B Q=1. When Q=0 and QB=1, M10 adds an off device in series with the leakage path through M8 and the path through M9, decreasing the leakage through those transistors. In an illustrative 65 nm technology, the pMOS devices generally have higher leakage than the nMOS devices and the leakage in M9 tends to hold node QBB near VDD, further limiting the leakage through M8 to the bitline by making its VGS negative. Even if QBB floats above 0 by only a small amount, the negative VGS in M8 reduces bitline leakage exponentially. When Q=1 and QB=0, M10 creates a stack of OFF nMOS transistors, reducing leakage through M7 by the stack effect. Since node QBB is held solidly at VDD, M8 has VDS=0, so bitline leakage is negligible. In both cases, M10 reduces the leakage relative to a nine transistor embodiment that does not include M10. However, for technologies in which nMOS leakage is greater than pMOS leakage, the extra transistor, M10, will not yield significant improvement over a 9T embodiment. Bitline leakage may be reduced by a variety of known circuit design techniques, which are contemplated within the scope of the present invention. For example, an inverter-connected NAND gate, with input RWL and output QB may be employed.

Evaluations of the illustrated embodiments reveal that, at 0.3V and nominal conditions, the 9T bitcell has 50% leakage overhead relative to a conventional 6T bitcell. The 10T bitcell reduces this overhead to 16%. Of course, although the 6T bitcell can hold data at this low voltage, it cannot function properly for either read or write accesses. Since a 6T bitcell at 600 mV has the same 6σ stability as a 10T bitcell at 300 mV, this overhead in leakage current is more than compensated by decreasing VDD by 300 mV relative to the 6T bitcell. In simulation, the 10T bitcell at 300 mV consumes 2.25× less leakage power than the 6T bitcell at 0.6V.

The reduction in sub-threshold leakage through M8 reduces the impact of leakage from unaccessed cells and yields the additional advantage of allowing more cells on a bitline during a read operation. Bitline leakage creates real problems for SRAMs in terms of leakage power and functionality during a read access. Leakage from the bitline into unaccessed bitcells causes undesirable voltage changes on the bitlines. Specifically, the bitline that should remain at its precharged value of VDD will droop. For differential sensing, this droop creates an effective voltage offset that the accessed cell must overcome before activating the sense amplifier. The delay created by overcoming the effective voltage offset results in longer read access times. For single ended read access like that used with the 10T cell, the steady-state voltage values for a ‘1’ and ‘0’ become more difficult to distinguish. For the same number of cells on a bitline, a 10T bitcell in accordance with the principles of the present invention produces larger bitline separation than a 6T (or 9T) bitcell. Sensing with an inverter should work well from 0° C. to 100° C., even with 256 cells on a bitline for the 10T cell. In contrast, the 6T cell (or 9T bitcell) would allow at most 16 bitcells on a bitline. The 10T bitcell allows a much higher number of bitcells on the bitline than the 6T bitcell across all process corners.

The schematic diagram of FIG. 5 provides a more detailed view of supply voltage float circuitry that may be employed in conjunction with a 10T sub-threshold SRAM cell in accordance with the principles of the present invention. The schematic illustrates the approach to a single row within a sub-threshold SRAM in accordance with the principles of the present invention. In an illustrative 65 nm technology, a conventional 6T bitcell cannot write with supply voltage below 0.6V, above threshold. The primary reason for write failure is the inability of the write driver and nMOS access transistor to win the ratioed fight against the pMOS inside the bitcell and to write a ‘0’. A virtual supply voltage VVDD is created by gating the supply using the signal VDDonBAR. A single power-supply-gating header switch connects node VVDD to the true power rail VDD. When the bitcell holds its data or during read accesses, VDDon=0 so that VVDD=VDD. During a write access, the virtual rail floats.

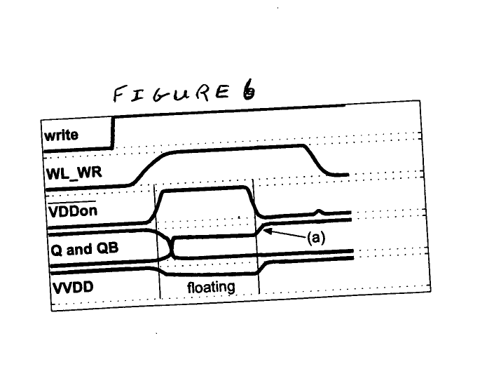

The timing diagram of FIG. 6 shows the timing associated with a write access using a float scheme in conjunction with a sub-threshold SRAM in accordance with the principles of the present invention. First, the ‘write’ signal goes high to indicate that a write access will occur, and the bitlines (BL and BLB in FIG. 5) are driven with the new data. Next, decoders drive a global wordline (not shown) which eventually causes the local write wordline (WLWR) to go high. Triggered by the local wordline, the VDDon signal goes high, allowing node VVDD to float. As the write access transistors discharge the virtual rail, its voltage droops, and Q and QB change to their new values. While VVDD continues to float, denoted by the “floating” label on the timing diagram, the logical ‘1’ the cell tracks its drooping voltage value. When VDDon goes low again while the local wordline remains high, it reconnects the virtual rail to the full supply. The feedback inside the bitcell then holds the Q and QB nodes at their correct logical values and amplifies the ‘1’ to full VDD. This occurs at point (a) in FIG. 6. Conventional SRAMs have employed a floating rail in the column-wise direction. The risk of the column-wise approach is that any droop that occurs on VVDD during a write operation will impact other unaccessed bitcells that are holding their data. For sub-threshold operation, the lack of voltage headroom increases the risk of losing data in those cells by decreasing their Hold SNM. For this reason, in the illustrative embodiment we implement the virtual rail along a row of the memory, as illustrated in FIG. 5. A conceptual row may be folded, so that its bitcells can share n-wells, and the entire row is written at once.

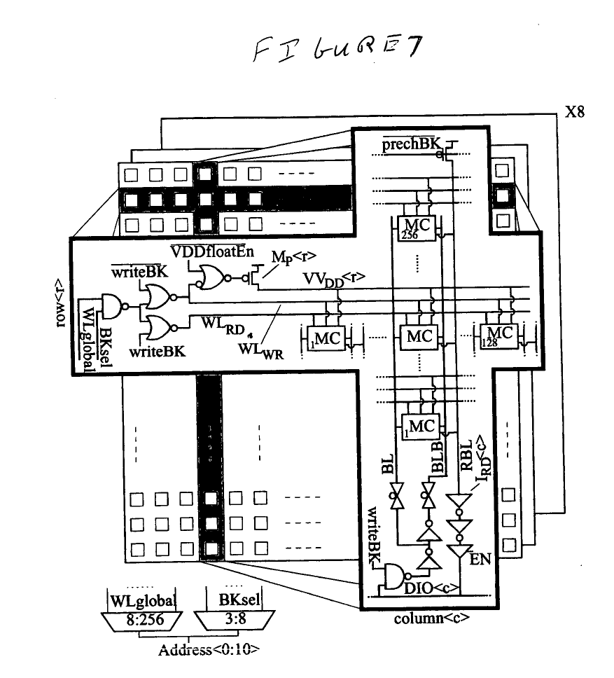

In the illustrative embodiment of FIG. 7, a 256 kb 65 nm bulk CMOS chip employs a 10T bitcell in accordance with the principles of the present invention. The memory is divided into eight 32-kb blocks. Each block contains an array of 256 rows and 128 columns of 10T bitcells. A single 128-bit Data Input/Output (DIO) bus serves all eight blocks. In this illustrative embodiment of a sub-threshold memory, only one read or write can occur per cycle. However, the 10T bitcell can accommodate both a read and write access to the same block in a single cycle. Such a dual-port embodiment of the memory includes a second DIO bus and additional peripheral logic. The decoder in this memory uses the top three address bits to determine the block and generates a block select signal (BKsel) to enable certain local features within the selected block. The remaining eight address bits select the correct row inside the block. The decoder decodes these eight bits and asserts a global wordline. The global word line then asserts a local wordline inside the selected block. The local wordline then combines with the local write signal to assert either WLRD or WLWR. For a write access, local logic turns on MP to the accessed row. The write drivers consist simply of inverters with transmission gates. Although unnecessary for functionality in this design, the transmission gates turn off when the memory is not writing to minimize leakage on the write bitlines (BL and BLB). The power supply to the WL drivers is routed separately to allow a boosted WL voltage. This technique improves the access speed and increases the robustness to local variations. The read bitline (RBL) is precharged prior to read access, and its steady-state value is ‘sensed’ using a simple inverter, IRDc. Tristate buffers prevent the output of the blocks from driving the DIO bus at the incorrect times. In this illustrative embodiment, one redundant row and column are available for each block.

In this illustrative embodiment, the n-wells are switched along a row along with VVDD. This approach makes it easier to follow design rules related to distance between well taps and avoided the need to route an additional VDD rail. To make this approach work, each row is folded such that a pair of 64-bit physical rows sharing n-wells and a VVDD rail makes up one conceptual 128-bit row. This folding increases the length of bitlines by roughly 2× and decreases the length of wordlines by roughly 2×. The n-wells of two separate rows can be shared and the VVDD for each row routed separately.

Wordline boosting and row/column redundancy go a long way towards removing bit errors even at very low voltages. With only one redundant row and column per block (<1% redundancy) and 100 mV wordline boosting, the memory functions to below 400 mV in the illustrative embodiment of FIG. 7. More redundancy can push this even lower. However, it is preferable to correct the bit errors at a more fundamental level.

Although inverters may be employed as sense amplifiers, read operations may be improved by tuning the switching threshold of each column on a column by column basis, for example, by adjusting the effective size of either the nMOS or pMOS by using different numbers of parallel devices. Other methods of biasing may also be employed. Local tuning is known in the art and employed, for example, to tune individual local clock buffers to balance skew.

In an illustrative embodiment, read operations may be improved by replacing the inverters with a different sensing scheme. Many such sensing schemes are known. For example, approaches to DRAM sensing that take an inherently single-ended bitcell and convert to pseudo-differential sensing may be employed in accordance with the principles of the present invention.

The main limitation with writing is that the voltage droop on VVDD does not develop sufficiently for the weakest cells on the row to switch the cell data. The leakage through the VVDD pull-up switch may be too strong on some rows because of device variation. In an illustrative embodiment, MP may be implemented as a stack of multiple series transistors to close leakage current. Applying RBB directly to MP has the same effect. Since MP is a pMOS, a triple well process is unnecessary. It is not fundamentally necessary to tie the n-wells along a row to VVDD. Instead, at the cost of routing a separate VDD to tap to the n-wells, the n-wells of all rows can stay at VDD even during write access. Then, the row whose virtual rail floats will experience RBB in its pMOS transistors. This allows the nMOS access transistors to overpower the bitcell feedback in the presence of less voltage droop on VVDD.

In another illustrative embodiment that maintains the same basic architecture and approach is to induce a specific voltage drop in VVDD intentionally. In the extreme, replacing MP with an inverter will drive VVDD all the way to 0V. Then, as long as the write wordline remains asserted, the bitcells will develop the correct internal data when VVDD goes back high regardless of local variations. A disadvantage of this extreme case is the energy penalty associated with discharging and re-powering the VVDD rail and all of the bitcells in the row. An alternative is to use a circuit to (e.g., a diode-connected FET) to force VVDD to some intermediate value that is low enough to ensure write, but that uses less energy.

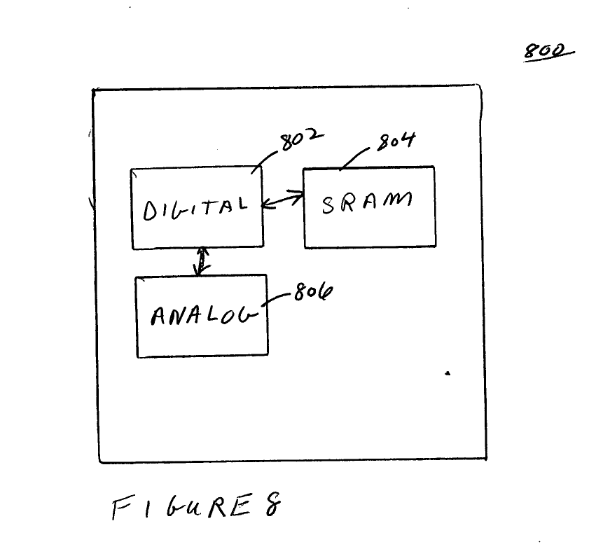

In the block diagram of FIG. 8 a mixed use circuit 800 in accordance with the principles of the present invention. The circuit 800 includes digital logic circuitry 802 in communication with sub-threshold SRAM 804. The sub-threshold SRAM may, for example, be formed of bitcells such as the 10T bitcell discussed in the description related to FIG. 3. Analog circuitry 806 may also be included in such a mixed-used circuit 800. In addition to the sub-threshold SRAM, the digital logic circuit 802 and the analog circuitry 805 may be configured to operate in the sub-threshold region. The analog circuitry 806 may include a sensor, for example.

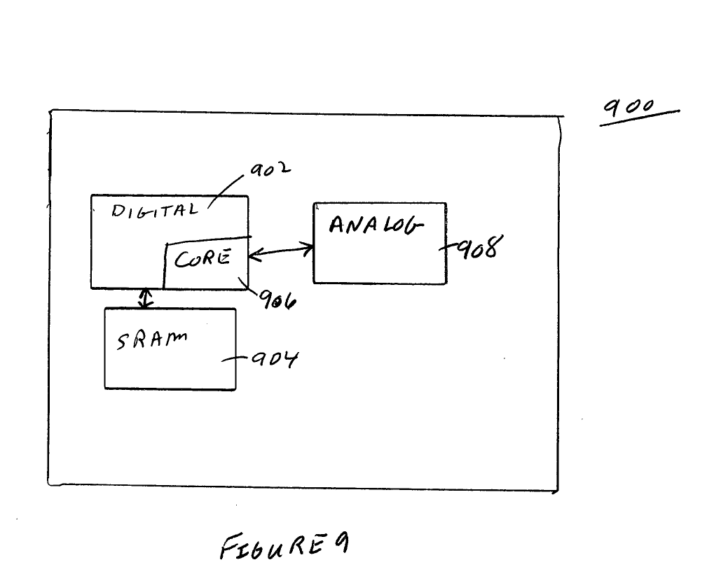

The block diagram of FIG. 9 illustrates the components of a mixed use circuit 900 that includes digital logic 902 and sub-threshold SRAM 904 in accordance with the principles of the present invention. In this illustrative embodiment, the digital logic 902 includes a microprocessor core 906. The core 906 may take the form of any type of conventional microprocessor core. The digital circuitry may include circuitry, such as, nonvolatile memory to thereby form a microcontroller. Analog circuitry 908 may also be included in the mixed use circuit 900. The core 906, digital logic circuitry 902, and analog circuitry 908 may all, or in any combination, be configured for operation at sub-threshold voltages.

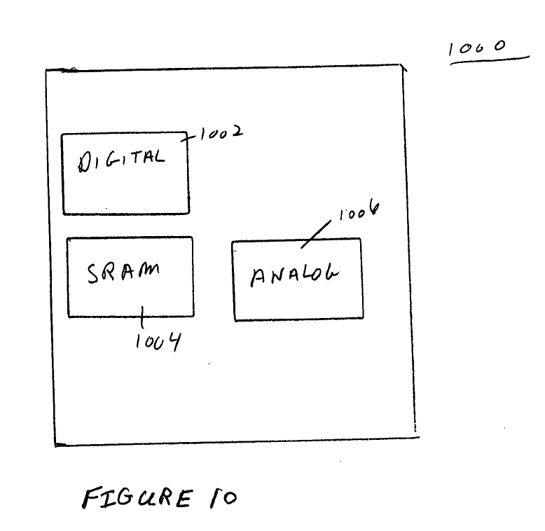

The block diagram of FIG. 10 illustrates the components of a portable electronic device 1000 that incorporates a sub-threshold SRAM in accordance with the principles of the present invention. The device 1000 includes digital circuitry 1002 and sub-threshold SRAM in accordance with the principles of the present invention 1004. Analog circuitry 1006 may also be included. The device 1000 may take the form of a cellular telephone, a media playback device such as an IPOD, for example, radio frequency identification tag, a microsensor node, a camera, or personal digital assistant (PDA), for example. Portable electronic devices 1000 in accordance with the principles of the present invention employ sub-threshold SRAMs in low power applications that also include distributed sensor networks, some of which must maintain long system lifetimes with severely constrained energy resources. Microsensor nodes include hardware that provide sensing, computation, and communications functionality. Microsensor nodes typically are restricted to small form factors and are thereby limited in their available power. Consequently, the extremely low power requirements of a sub-threshold SRAM in accordance the principles of the present invention is particularly well suited for operation in a microsensor node.

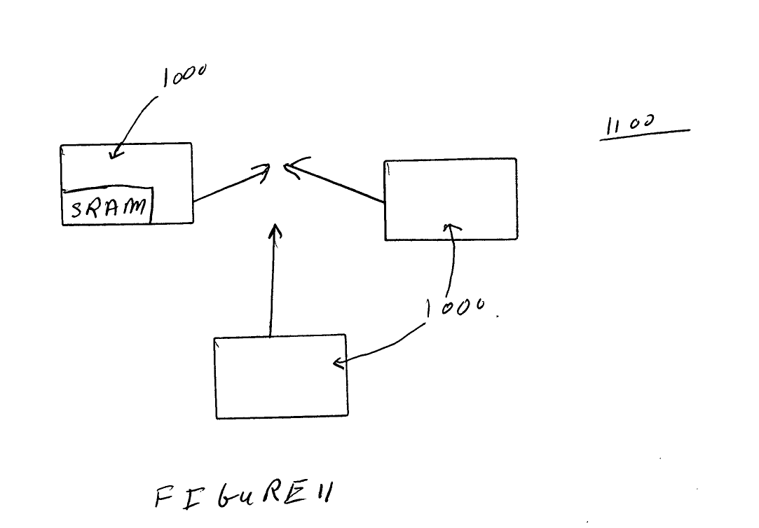

FIG. 11 is a block diagram of a network of portable electronic devices 1100 at least one of which includes an SRAM in accordance with the principles of the present invention. A wireless micro-sensor network in accordance with the principles of the present invention may include thousands of distributed nodes 1000 that sense and process data and relay it to an end-user. Node networks in accordance with the principles of the present invention may be employed, for example, in habitat monitoring. Habitat monitoring involves long-term data collection from a natural environment, primarily for scientific study. Environmental observation and forecasting systems are similar to habitat monitoring system, but they cover a much larger geographic area. Nodes in accordance with the principles of the present invention are also suitable for application in environmental observation and forecasting systems. Microsensor nodes in accordance with the principles of the present invention are also suitable for application in health systems in which the nodes may be implanted and, therefore limited in access to power sources. One example of an implantable micro-sensor is an artificial retina. Structural health monitoring, target tracking, and biological and chemical sensing are other applications for which a microsensor that employs a sub-threshold SRAM in accordance with the principles of the present invention are particularly well-suited.

The foregoing description of specific embodiments of the invention has been presented for the purposes of illustration and description. It is not intended to be exhaustive or to limit the invention to the precise forms disclosed, and many modifications and variations are possible in light of the above teachings. The embodiments were chosen and described to best explain the principles of the invention and its practical application, and to thereby enable others skilled in the art to best utilize the invention. It is intended that the scope of the invention be limited only by the claims appended hereto.

What is claimed is:

1. An electronic memory comprising:
a plurality of transistors operationally connected to form a bistable circuit, the transistors being characterized by a threshold voltage, VT;
power connections formed within the bistable circuit for connection to power and reference supply voltages, wherein the bistable circuit is configured for operation with connection to power and reference supplies having a potential difference, VDD, between the power and reference supplies that is less the bistable circuit's constituent transistors' threshold voltage VT; and
circuitry configured to buffer data stored by the bistable circuit during a read access to the bistable circuit.

2. The circuit of claim 1 further comprising circuitry configured to float the connection to said power supply during a write access to the bistable circuit.

3. The circuit of claim 1 wherein a plurality of memory circuits are formed to operate as a static memory array and the circuit further comprises digital logic circuitry configured for operation with the memory array.

4. The circuit of claim 3 wherein the digital logic circuit comprises a microprocessor core.

5. An electronic memory comprising:
a plurality of transistors operationally connected to form a bistable circuit, the transistors being characterized by a threshold voltage, VT;
power connections formed within the bistable circuit for connection to power and reference supply voltages, wherein the bistable circuit is configured for operation with connection to power and reference supplies having a potential difference, VDD, between the power and reference supplies that is less the bistable circuit's constituent transistors' threshold voltage VT; and
circuitry configured to float the connection to said power supply during a write access to the bistable circuit.

6. The circuit of claim 5 further comprising circuitry configured to buffer data stored by the bistable circuit during a read access to the bistable circuit

7. The circuit of claim 5 wherein a plurality of memory circuits are formed to operate as a static memory array and the circuit further comprises digital logic circuitry configured for operation with the memory array.

8. The circuit of claim 7 wherein the digital logic circuit comprises a microprocessor core.

9. An integrated circuit memory comprising:
first pullup and pulldown transistors configured to form a first inverter having input and output nodes, with binary signals coupled to the input forcing the output to the opposite binary signal value;
second pullup and pulldown transistors configured to form a second inverter having input and output nodes, with binary signals coupled to the input forcing the output to the opposite binary signal value, the input of the first inverter being connected to the output of the second inverter, and the output of the first inverter being connected to the input of the second inverter, thereby forming a bistable circuit, wherein the transistors are characterized by a threshold voltage VT; wherein the first and second inverters are configured for operation with connection to power and reference supplies having a potential difference, VDD, between the power and reference supplies that is less the inverter's constituent transistors' threshold voltage VT; and
circuitry configured to buffer data stored by the memory circuit during a read access to the bistable circuit.

10. The memory circuit of claim 9 further comprising circuitry configured to float the connection to said power supply during a write access to the bistable circuit.

11. The memory circuit of claim 9 further comprising circuitry configured to float the connection to said reference supply during a write access to the bistable circuit.

12. The memory circuit of claim 10 wherein the buffer circuitry comprises:
third pullup and pulldown transistors connected to form a third inverter having an input and an output, the input being connected to the input of the first inverter and output of the second inverter.

13. The memory circuit of claim 12 wherein the inputs of the first and second inverters are accessed for a write operation through access transistors enabled by a word line.

14. The memory circuit of claim 13 wherein the output of the third inverter is configured for read access enabled by word and bit lines separate from the write word and bit lines.

15. The circuit of claim 9 wherein a plurality of memory circuits are formed to operate as a static memory array and the circuit further comprises digital logic circuitry configured for operation with the memory array.

16. The circuit of claim 15 wherein the digital logic circuit comprises a microprocessor core.

17. A static random access memory array comprising:
a plurality of static random access memory cells, each cell comprising a bistable circuit including two pullup transistors, two pulldown transistors, and two pass transistors; and buffer circuitry configured to buffer data stored by the bistable circuit during a read access to the bistable circuit all of which transistors are configured for operation at a voltage less than the threshold voltage of the constituent transistors.

18. The static random access memory array of claim 17 further comprising: float circuitry configured to float the connection to a power supply during a write access to the bistable circuit.

19. The circuit of claim 18 further comprising circuitry wherein a plurality of memory circuits are formed to operate as a static memory array and the circuit further comprises digital logic circuitry configured for operation with the memory array.

20. The circuit of claim 19 wherein the digital logic circuit comprises a microprocessor core.

21. The circuit of claim 19 further comprising analog circuitry.

22. The circuit of claim 21 wherein the analog, digital, and memory circuits are configured to operate as a microsensor node.

23. The circuit of claim 21 wherein the analog, digital, and memory circuits are configured to operate as a portable electronic device.

24. The circuit of claim 23 wherein the electronic device is a cellular telephone.

25. The circuit of claim 23 wherein the electronic device is a camera.

26. The circuit of claim 23 wherein the electronic device is a media player.

27. The circuit of claim 9 further comprising circuitry configured to reduce bitline leakage current.
